(19) United States
(12) Patent Application Publication
(10) Pub. No.: US 2015/0229102 A1
(43) Pub. Date: Aug. 13, 2015

(54) METHOD AND APPARATUS FOR DISABLING A LASER

(71) Applicant: TEXAS INSTRUMENTS INCORPORATED, Dallas, TX (US)

(72) Inventors: Sajjad Ali Khan, Plano, TX (US); Eric Henry Pruett, Denton, TX (US)

(21) Appl. No.: 14/295,138

(22) Filed: Jun. 3, 2014

Related U.S. Application Data
(60) Provisional application No. 61/939,454, filed on Feb. 13, 2014.

(51) Int. Cl. H01S 5/042

(52) U.S. Cl. CPC H01S 5/042

(57) ABSTRACT

An illumination module configured for insertion within a housing has a laser diode and a drive circuit for applying current or voltage to the laser diode at a first magnitude and in a first direction to cause the laser diode to emit laser light in a normal operating mode. An interlock connects the illumination module when inserted within the housing. The interlock has a mechanism configured to automatically modify the drive circuit when the module is removed from the housing, so that current or voltage is applied to the laser diode at a second magnitude and in a second direction opposite to the first direction that permanently damages the ability of the laser diode to emit the laser light that is emitted in the normal operating mode.

This application claims the benefit of Provisional Application No. 61/939,454, filed Feb. 13, 2014, and the entirety of which is hereby incorporated by reference

This relates generally to methods and apparatus for disabling solid state laser diodes or the like.

### BACKGROUND

Optical diode lasers use optical pumping to emit photons. Materials with a direct band gap typically result in favorable optoelectronic properties over indirect band gap materials. By alloying certain semiconductor materials such as aluminum (Al), gallium (Ga), arsenic (As), indium (In), and phosphorus (P), among others, it is possible to vary the wavelength of the emitted light within limits defined by the ratio of direct to indirect band gap materials. See, K. Hajiaghajani “Design of an Optimum Driver Circuit for CW Laser Diodes,” MSEE Thesis, Univ. of Arizona (1992) (UMI Ann Arbor, Mich., Order No. 1351355), incorporated herein by reference.

Diode lasers may be implemented in assemblies of one or more lasers. Light emitting lasers emit light at a high intensity and a narrow wavelength. There is a risk that a laser diode may be removed from a projection system and misused once it is removed. If it is misused, it may cause injury or damage when powered.

One approach, described in US 2012/0280578 A1, creates a laser interlock by attaching hardware with intelligent logic. Such approach shuts the laser system off in the event of programmed interlock signals.

Another approach, described in U.S. Pat. No. 4,242,657 A and U.S. Pat. No. 2,573,920 A, makes use of electrical connectors to shut off or turn on energy to a magnet which completes a circuit. The laser is rendered non-operational without power to the circuit but otherwise remains functional.

Yet other approaches incorporate automatic shut-off systems which monitor the laser enclosure and temporarily shut off the laser if a part of the enclosure is opened or the laser beam is interrupted.

Such interlocks are designed to prevent accidental exposure to laser hazards. In these interlocks, the laser is temporarily turned off or the system shut down if either the interlock is tripped or the laser beam is interrupted. The laser device itself, however, remains undamaged and otherwise fully functional. Thus, power can be restored and system interlocks can be reset to turn the laser back on. So, these types of interlocks do not address the issue of laser misuse once the laser is removed from its protective housing and repowered for reuse elsewhere.

### SUMMARY

Methods and apparatus are provided for disabling a laser diode.

In an implementation, a laser illumination module including a laser diode is configured with an interlock that automatically applies a reverse current to the laser sufficient to disable its normal functioning upon unauthorized removal of the module from the system in which it is deployed.

A described module, employing a laser diode, laser drive circuitry for powering the laser diode and a Zener diode for laser diode current control, is provided with a rechargeable battery that charges during normal laser operation and an interlock switch that applies reverse current to the laser diode when the interlock switch is tripped. The reverse current damages the laser diode leaving it unable to further function at its usual high intensity (e.g., turns it into a low power dark emitting laser diode (DELD), turns it into a very expensive LED, or renders it completely inoperable).

### BRIEF DESCRIPTION OF THE DRAWINGS

Example embodiments are described with reference to accompanying drawings, wherein:

FIG. 1 illustrates the underside of a laser projector showing an access opening for receiving a laser illumination module.

FIG. 2 is a simplified circuit schematic view of a laser diode in parallel with a Zener diode.

FIG. 3 shows a voltage vs. current profile for a typical Zener diode.

FIGS. 4A-4B are schematic views showing an example illumination module in normal and interlock triggered operation modes.

FIG. 5 is a flow diagram illustrating a laser evaluation sequence.

FIG. 6 is a flow diagram illustrating a laser diode damage sequence.

FIGS. 7 and 8 are example graphical representations of voltage and current characteristics of a Zener diode during normal and laser disabling operation modes.

### DETAILED DESCRIPTION OF EXAMPLE EMBODIMENTS

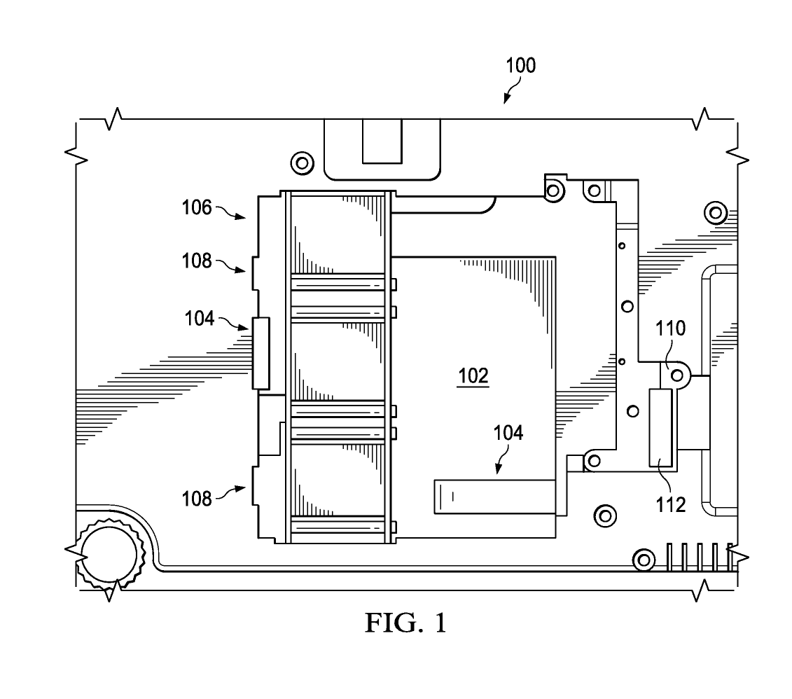

FIG. 1 illustrates the underside of a laser projector 100 for display of images using a light modulator, such as a Texas Instruments DLP® digital micromirror device (DMD) spatial light modulator (SLM), for modulating light received from an illumination source such as a laser illumination module of a type addressed herein. The underside includes an access opening for receiving the laser module within a cavity 102 provided in the interior of the projector 100. Flex cables 104 serve to establish electrical connection of a power source and other circuitry of the projector with corresponding elements of the module, and fans 106 are provided to cool the installed module during normal operation. Tab receiving cutouts 108 and threaded screw opening 110 or the like enable attachment of a cover plate over the opening after receipt of the module. The screw opening at 108 may provide the mechanical contact by which an interlock is triggered. A mechanical interconnect switch 112 may be provided to disconnect the projector power source to prevent powering the laser module when the cover is removed. The operation of such switch may be modified to provide a module interlock mechanism for disabling the laser, as further described below.

Laser diodes are sensitive to overvoltage and overcurrent conditions. Such conditions may cause the optical energy density to exceed the diode's integral mirror reflective capacity whereby the mirrored surface can lose its reflectivity and interfere with proper functioning. Such conditions may also cause failure of the laser diode's PN junction. A severe overcurrent or overvoltage surge can cause localized heating and other harmful phenomena which, under extreme conditions, can fracture the laser diode die. See, US 2011/0110005 A1, the entirety of which is incorporated herein by reference.

It is not unusual for laser illumination modules to include multiple low power lasers in series. Low power laser diodes whose optical output power is below around 200 mW are particularly sensitive to overvoltage/overcurrent surges. Such diodes are typically designed as inherently fast devices suitable for direct modulation at data rates in the gigahertz range. Thus, the PN junction and optical elements of the laser diode can react very quickly to changes in voltages or current, and need to be proactively protected to prevent the occurrence of overvoltage or overcurrent conditions. See, US 2011/0110005 A1.

As discussed for an example current vs. voltage profile of a laser diode shown in US 2011/0110005 A1, the voltage vs. current profile of the laser diode is similar to that of other types of diodes. For the example laser diode discussed in US 2011/0110005 A1, starting from zero volts and applying incremental positive increases in voltage (i.e., those voltages that would tend to forward bias the laser diode), very little current flows until around 1.8 volts is reached. Thereafter, applying further incremental positive increases from around 1.8 volts up causes current flow to increase at a roughly exponential rate until the current exceeds a lasing threshold, which, for the example laser diode referenced there, occurs at around 2.2 volts and at around 30 milliamps. With further incremental positive increases in voltage, current flow continues to increase, while the optical power emitted by the laser diode increases at a rate that is roughly proportional to current. Once the maximum design current for a particular laser diode is reached (which is around 35 milliamps and 2.4 volts for the given example laser diode), further increases in current will likely result in failure, caused by one or both of the damage mechanisms described above.

Thus, as discussed in US 2011/0110005 A1, it can be important to completely prevent voltage, and thus current, from increasing beyond the absolute maximum rating for the particular laser diode. And, in many cases (most cases for low power laser diodes), the laser diode will be destroyed if the absolute maximum ratings are exceeded, even for a brief period of time. So, in order to protect the laser diodes from being damaged, positive protection is provided to limit both positive and negative voltages and/or currents across the diode. Examples of such protection are discussed, for example, in U.S. Pat. No. 5,550,852 A; U.S. Pat. No. 6,028,878 B; U.S. Pat. No. 8,264,806 B2; and US 2011/0110005 A1, the entireties of all of which are incorporated herein by reference. The recommendation given in US 2001/0110005 A1 is to limit positive voltages to around 2.4 volts and negative voltages to around 2.0 volts or less.

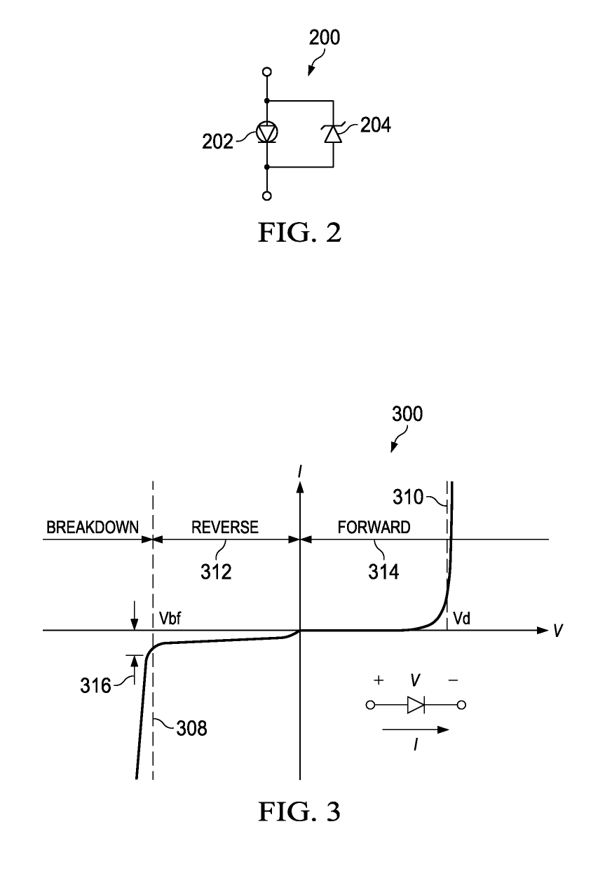

The need for such protection is especially true for laser diodes designed to be inherently fast devices. Accordingly, commercial diode laser illumination modules will typically include a reverse connected Zener diode, photodiode or similar protective device (hereafter “Zener diode”) in parallel with each laser diode. A simplified schematic view of a circuit arrangement 200 having a laser diode 202 in parallel with a reverse connected Zener diode 204 is shown in FIG. 2.

FIG. 3 illustrates a typical current versus voltage profile (j vs. v) 300 for the Zener diode 204. The Zener diode 204 is used to constrain voltage v between a breakdown voltage V_{br} 308 in reverse bias 212 and another smaller voltage V_{d} 310 in forward bias 314. The breakdown voltage V_{br} 308 is often referred to as the Zener voltage V_{Z}. In forward bias 314, voltage v is restricted between V_{d} and zero. If voltage v exceeds V_{d}, current j is unrestricted in the positive direction and the diode 304 will break down. In reverse bias 312, the Zener diode 204 limits voltage v to V_{br} in the event of an overvoltage or overcurrent occurrence. Until V_{br} is exceeded, there is a low level leakage current 316 which flows through the Zener diode 204 in reverse bias 312. The Zener diode 204 offers no or low resistance to the current j after voltage v exceeds V_{br}. If either voltage discharge or current pulse exceed the Zener's diode 204's limits, the Zener diode 204 will break down.

While the reverse connected Zener diode 204 may be adequate to protect the laser diode as connected in normal laser diode operation, it will not protect the laser diode the same way if the normally applied polarity direction (“+” to “−” or “−” to “+,” depending on laser design) is reversed and the polarity is connected in a reversed, opposite polarity (viz., reversal of bias “−” to “+” or “+” to “−”) direction.

The Zener diode 204 limits voltage v and current j through the normally connected laser diode 202. If laser diode 202 is designed for normal forward bias operation (laser diode 202 connected “+” to anode, “−” to cathode with Zener diode reverse connected “−” to anode, “+” to cathode) and applied current j or voltage v is limited between V_{d} in forward bias and V_{br} in reverse bias, current j through Zener diode 204 is limited to approximately zero in forward bias and a low leakage level in reverse bias. If applied current j or voltage v is outside of the range of V_{d} in forward bias and V_{br} in reverse bias, the diode 204 breaks down and current flow is unrestricted. If current j limit through Zener diode 204 is exceeded, voltage v is also exceeded past breakdown. Either voltage or current excess can cause the Zener diode 204 to break down. Once Zener diode 204 breaks down, the circuit 200 will no longer protect laser diode 202 against a current or voltage greater than its maximum limit. When this occurs, too high a voltage or current pulse will permanently destroy the normal operation of laser diode 202, rendering it totally inoperable or at least capable of operation at only reduced power levels.

Table 1 lists maximum current I(max) and maximum voltage V(max) values for several commercially available laser diode devices having Zener diodes or similar protective devices coupled to the laser diode element. The first listed device indicates an allowable upper current limit of 85 mA. If the reverse current I(max) is exceeded beyond 85 mA (plus any provided safety margin), the Zener diode will exceed its breakdown voltage and lose its protective function. The second and third listed laser diodes indicate reverse voltage limits of 2V. After breakdown, the laser diode will be left unprotected and vulnerable to destruction, especially to suddenly applied current/voltage impulses or spikes.

TABLE 1

| Diode Laser | I (max) | V (max) |
|---|---|---|
| Nichia NDV4316 | 85 mA | |
| Sanyo DL3148-037 | | 2 V |
| Sanyo DL3149-057 | | 2 V |

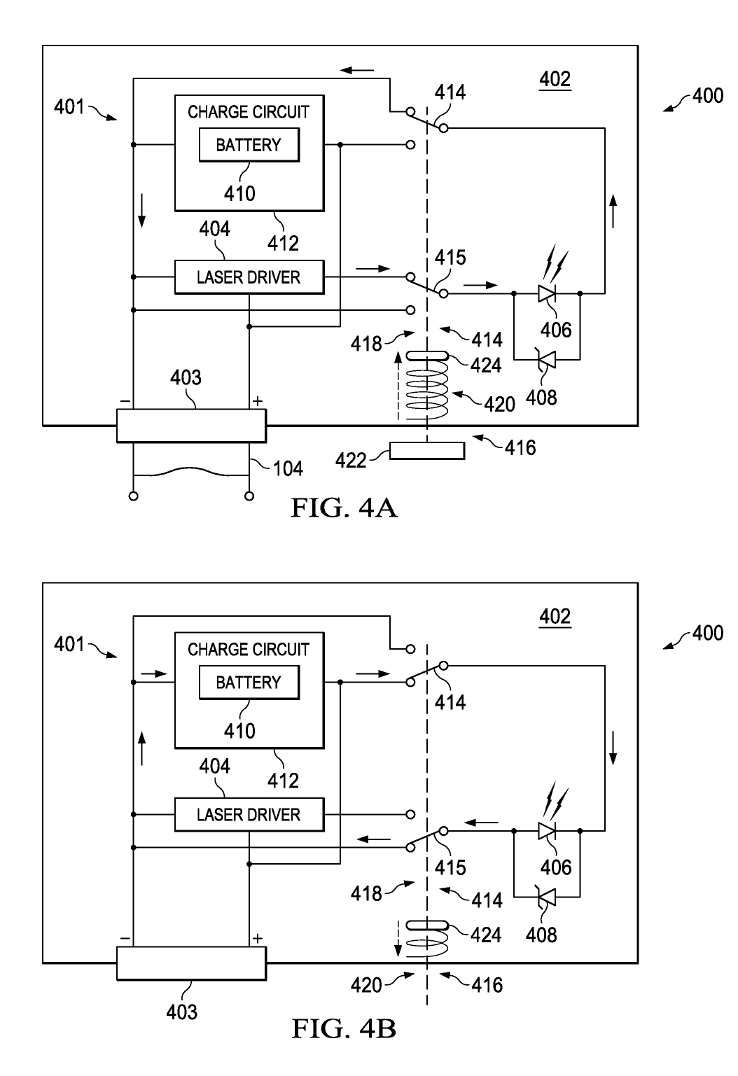

An example embodiment laser illumination module 400 is shown in FIGS. 4A and 4B. The example embodiment takes advantage of the characteristics of a Zener diode to create an interlock that disables normal operation of the laser upon removal of the module from an operating system, such as upon its removal from cavity 102 of laser projector 100 shown in FIG. 1.

The illustrated module 400 has a circuit 401 enclosed within a housing 402. Circuit 402 includes a laser driver 404 connected for driving a laser diode 406 under power supplied by system 100 through a flex cable 104 connected to a cable connector 403 when housing 402 is brought within cavity 102. A Zener diode, photodiode or similar protective element (collectively “Zener diode”) 408 is reverse coupled in parallel with laser diode 406 to provide overvoltage/overcurrent protection to laser diode 406 during normal operation. Circuit 401 further includes a rechargeable battery 410 and a charge circuit 412 connected for charging battery 410 also under power supplied by system 100 through flex cable 104.

Module 400 has an interlock 414 that includes switches 414, 415 and a switch controller 416. Switch controller 416 controls switches 414, 415 to connect the laser diode 406/reversed Zener diode 408 coupling to laser driver 404 in a normal operating polarity direction for normal operation as shown in FIG. 4A, and to connect the laser diode 406/reversed Zener diode 408 coupling to battery 410 in an opposite, reversed polarity direction in interlock triggered operation as shown in FIG. 4B.

FIGS. 4A and 4B illustrate a simple switch controller 416 in the form of a mechanical interlock with a movable shifter 418 that has a protruding end which is pushed inwardly toward housing 402 (up arrow direction in FIG. 4A) against a mechanical bias of a tension spring 420 and brought to resting abutment with a mechanical stop 422 on projector 100 when module 400 is placed in cavity 102. Spring 420 has one end secured to an interior wall of housing 402 and another end secured to an attachment point 424 on shifter 418 that moves inwardly with shifter 418 as shifter 418 is pushed in during insertion of module 400 into cavity 102. In the module inserted position (FIG. 4A), the inwardly pushed shifter 418 sets switches 414, 415 to a normal laser operation mode switch setting wherein laser driver 404 is connected to apply voltage/current in normal polarity direction to operate laser diode 406 to provide laser illumination. When module 400 is removed from cavity 102, the abutting end of shifter 418 is freed from stop 422 and shifter 418 moves outwardly away from housing 402 (down arrow direction in FIG. 4B) to a relaxed position under action of release of stored energy by tension spring 420. In the module removed position (FIG. 4B), the outwardly released shifter 418 sets switches 414, 415 to an interlock triggered operation mode switch setting wherein the charged battery 410 is connected to apply voltage/current in opposite, reversed polarity direction to disable and permanently downgrade further functioning of laser diode 406.

It will be appreciated that switch controller 416 may take many forms and that control of switching between normal operation and interlock triggered operation modes may be effected through mechanical operation, electrical operation, a combination of both mechanical and electrical operations, or some other means. The arrangement shown in FIGS. 4A and 4B is merely one simple illustration. Details of interlocking and switch control implementations will vary depending on system application, module configuration, and individual preferences.

During the normal mode of operation, with module 400 inserted in projector cavity 102 so switches 414, 415 are set as shown in FIG. 4A, circuit 401 functions to drive the laser diode 406/reversed Zener diode 408 coupling with power applied through projector flex cable 104 via laser driver 404 in the normal laser operation polarity current flow direction. This is illustrated by arrows showing a counterclockwise current flow path direction from laser driver 404 through laser diode 406 in FIG. 4A for a laser diode 408 designed for normal forward bias operation (“+” polarity applied to anode; “−” polarity applied to cathode) with a Zener diode 408 coupled for normal reverse bias operation (“−” polarity applied to anode; “+” polarity applied to cathode). (A laser diode designed for normal reverse bias operation will be oppositely connected.) The normal mode of operation causes laser diode 406 (which may be one of a bank of series connected multiple laser diodes) to emit laser light for use such as a laser illumination source for projecting and image through modulation of incident light by modulating elements of a spatial light modulator, or the like.

During the same normal mode of operation, with module 400 inserted in projector cavity 102 and switches 414, 415 set as shown in FIG. 4A, circuit 410 also functions to charge battery 410 with power applied through the flex cable connection 403 to drive the battery charge circuit 412. This places battery 410 in a charged state.

Upon unauthorized removal of module 400 from the projector cavity 102, the mechanism and/or electrical circuit elements of interlock 414 function to control switches 414, 415 to reset them as shown in FIG. 4B. This places circuit 401 in the interlock triggered operation mode, with the normal polarity connection of laser driver 404 to the laser diode 406/reversed Zener diode 408 coupling disrupted and the laser diode 406/reversed Zener diode 408 coupling reconnected with power now applied from charged battery 410 in an opposite, reversed polarity current flow direction. This is illustrated by arrows showing a clockwise current flow path direction from battery 410 through laser diode 406 in FIG. 4B. The interlock triggered mode of operation causes a transient current surge in the opposite direction to the laser diode 406/reversed Zener diode 408 coupling. Charge circuit 412 and battery 410 are configured so that the applied surge disrupts protection by Zener diode 408 and damages further normal functioning of laser diode 406. For example, a typical laser diode having a maximum allowable reverse current limit of 85 mA may be permanently damaged by applying a 100 ms pulse at a reverse current of 900 mA. At this current, the voltage required for breakdown is from about −5.5V to about −7V.

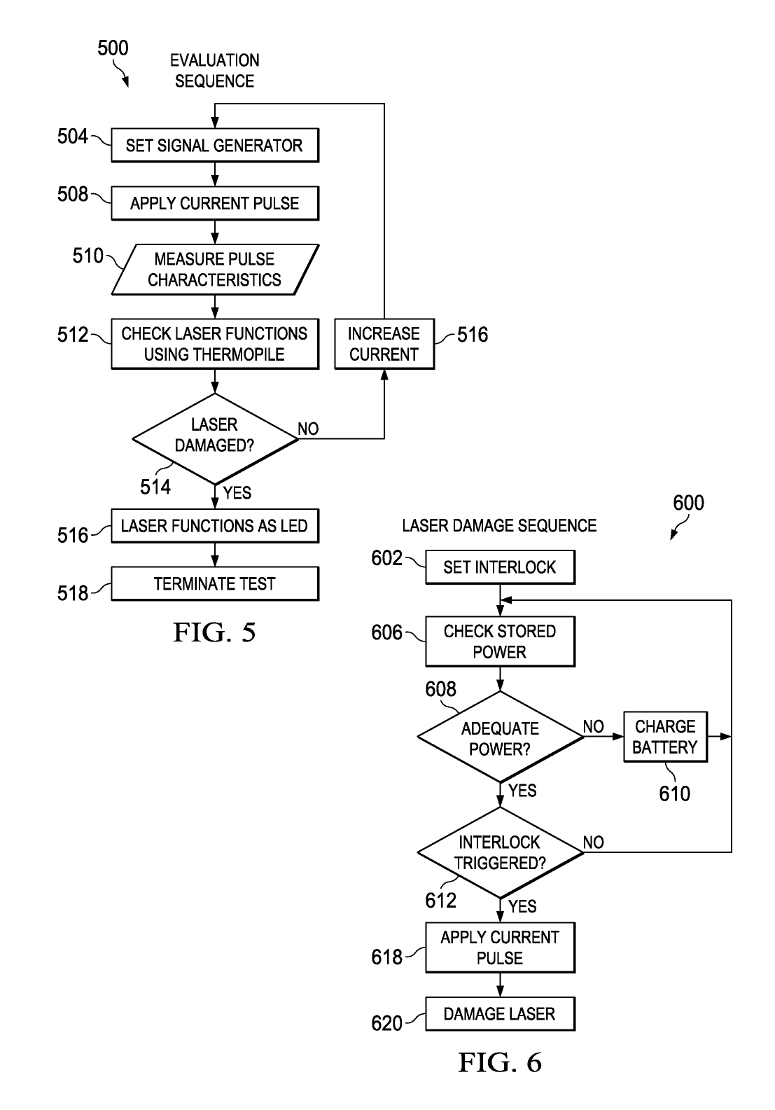

FIG. 5 illustrates a flow diagram of an example sequence 500 used to determine breakdown of a laser diode.

A signal generator is set to output a current pulse (block 504). The current pulse is applied (block 508). Pulse characteristics are measured (block 510) to identify the current pulse needed to break down the laser diode. The laser diode functioning is checked (block 512) using a device such as a thermopile. If the measurement shows that the laser diode is undamaged (“No” path from block 514), then current is increased (block 516) and the sequence is repeated (blocks 504-514). If the measurement shows that the laser diode is damaged (“Yes” path from block 514), then the high power lasing ability has been disabled and the diode now either doesn't function at all or functions only at reduced capability, e.g., as a light emitting diode (LED) (block 516). The test sequence is then terminated (block 518).

FIG. 6 illustrates a flow diagram of an example sequence 600 used to trigger the interlock.

The sequence 600 begins with setting the interlock (block 602). The stored battery power is checked (block 606). If stored power is inadequate to disable laser functioning in interlock triggering mode (“No” path from block 608), the battery is charged (block 610). If the stored power is adequate (“Yes” path from block 608), the interlock is checked (block 612) to evaluate whether it has been triggered. If the interlock has not yet been triggered (“No” path from block 612), the sequence repeats (blocks 606-612). If the interlock has been triggered (“Yes” path from block 612), a polarity reversal current pulse is applied to the laser diode/reversed Zener diode coupling (block 618). This causes the Zener diode to exceed its breakdown current/voltage limit and lose its ability to protect the laser diode. This enables current/voltage higher than maximum allowable limits to be applied to the laser diode, and the lasing function is permanently damaged (block 620).

During testing of the described approach, a signal generator was used as a power source, where the current is controlled and applied in a single pulse of about 100 ms. An oscilloscope monitors both power supply current and voltage.

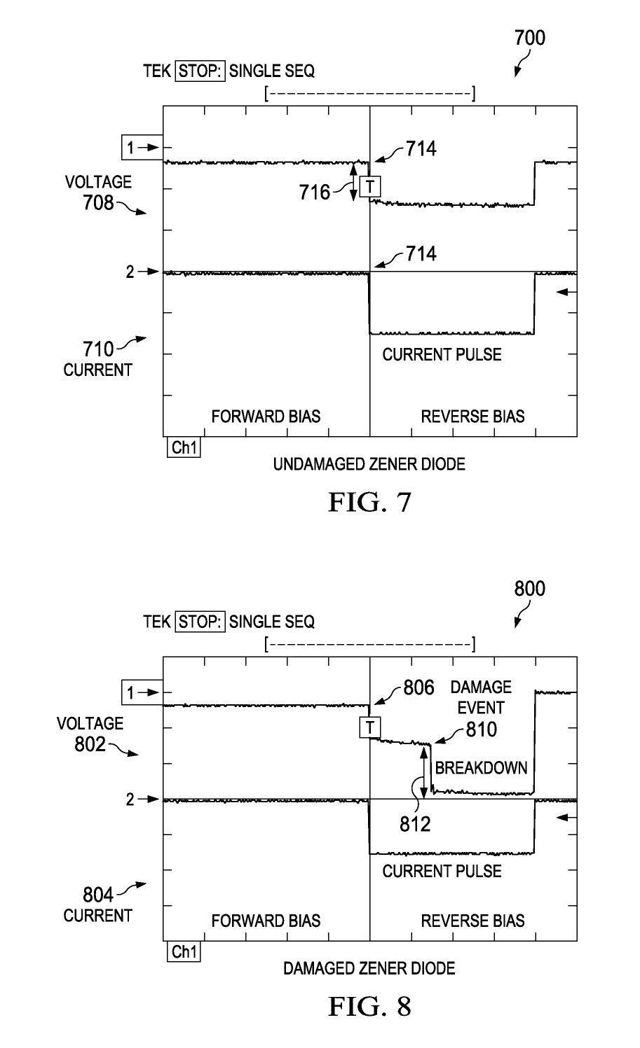

FIGS. 7 and 8 illustrate oscilloscope screen capture images of a test in which a signal generator is used to apply a current in a single pulse of about 100 ms duration to a laser diode/Zener diode laser assembly.

FIG. 7 shows the image 700 of voltage 708 and current 710 through the assembly. Forward bias is shown on the left side and reverse bias is shown on the right side of the image 700 due to reverse biasing of the Zener diode. A current 712 applied to the assembly is slowly decreased from forward to reverse bias. The current 710 through the Zener diode remains low as applied current is decreased. Voltage 708 is unchanged throughout the forward bias. At point 714, the applied current 712 is further decreased to put the Zener diode into reverse bias. After point 714, current 710 is low with a small voltage drop 716. Voltage 708 across the Zener diode remains unchanged for a current pulse up to −760 mA. The assembly is undamaged.

FIG. 8 is another screen capture image 800 from an oscilloscope of voltage 802 and current 804 through the assembly comprised of a Zener diode and a laser diode. Here, applied current 712 is decreased through forward bias until reverse bias at point 806. Voltage 802 drops slightly through the diode laser and there is a small leakage current 808 through the diode until point 810. The laser diode breaks down at point 810 when the applied current decreases past the threshold value of −780 mA. The voltage drop 812 shows diode breakdown.

Example testing with various diode lasers showed permanent laser diode damage thresholds in a range of −750 mA to −900 mA at a 100 ms current pulse. As the magnitude of the reverse current pulse is increased, permanent diode laser damage occurs more closely to the beginning of the current pulse. A current pulse was able to damage the laser diode even when ramping a direct current (DC) reverse current did not damage the Zener diode. After damage to the diode laser diode, the laser was unable to lase yet still emitted a lower power light at about 20 mW at 1.2 A.

As discussed previously, a commercial laser diode product may typically include a reverse connected Zener diode coupled for protection of the laser diode (or multiple reverse connected Zener diodes, photodiodes or similar protective devices respectively coupled to ones of multiple laser diodes.) The Zener diode is effective as protection for a small current pulse and voltage. Beyond this range, the Zener diode can break down, allowing a much larger voltage or current pulse through the diode laser. This larger voltage or current pulse can permanently break down the diode laser.

This characteristic of diode laser modules is used to construct an interlock switch which, when triggered through unauthorized tampering with the module, will damage the laser diode to disable the lasing function. Bypass mechanisms/circuitry may, of course, be added by any number of means in order to enable authorized servicing of the modules and systems without triggering the destruction mode and/or without damaging the lasing function.

Those skilled in the art to which the invention relates will appreciate that modifications may be made to the described embodiments, and also that many other embodiments are possible, within the scope of the claimed invention.

What is claimed is:

1. Apparatus, comprising:
a housing;
an illumination module configured for insertion within the housing; the illumination module including a laser diode, and a drive circuit for applying current or voltage to the laser diode at a first magnitude and in a first direction to cause the laser diode to emit laser light in a normal operating mode; and
an interlock configured for connecting the illumination module when inserted within the housing; the interlock including a mechanism configured to automatically modify the drive circuit, upon removal of the illumination module from the housing, for applying current or voltage to the laser diode at a second magnitude and in a second direction opposite to the first direction to permanently damage the ability of the laser diode to emit the laser light emitted in the normal operating mode.

2. The apparatus of claim 1, wherein the housing includes a power source and an interior cavity for receiving the illumination module through an access opening with a removable cover; the illumination module is configured to connect the power source to the laser diode when the illumination module is inserted within the cavity with the cover over the access opening; and the interlock mechanism is configured to disconnect the power source from the laser diode when the cover is removed.

3. The apparatus of claim 2, wherein the illumination module includes a battery, and the interlock mechanism is configured to apply the current or voltage to the laser diode at the second magnitude and second direction by the battery.

4. The apparatus of claim 3, wherein one of the illumination module includes a battery charge circuit, and the battery charge circuit is configured to charge the battery by the power source when the illumination module is inserted within the cavity.

5. The apparatus of claim 4, wherein the laser diode comprises multiple low power laser diodes in series.

6. The apparatus of claim 5, wherein a reverse connected Zener diode is coupled in parallel with the laser diode.

7. The apparatus of claim 6, wherein the housing includes a spatial light modulator configured for modulating the laser light emitted in the normal operating mode.

8. The apparatus of claim 1, wherein the illumination module includes a battery, and the interlock mechanism is configured to apply the current or voltage to the laser diode at the second magnitude and second direction by the battery.

9. The apparatus of claim 8, wherein one of the illumination module includes a battery charge circuit, and the battery charge circuit is configured to charge the battery when the illumination module is inserted within the housing.

10. The apparatus of claim 1, wherein the laser diode comprises multiple low power laser diodes in series.

11. The apparatus of claim 10, wherein a reverse connected Zener diode is coupled in parallel with the laser diode.

12. The apparatus of claim 1, wherein a reverse connected Zener diode is coupled in parallel with the laser diode.

13. The apparatus of claim 1, wherein the housing includes a spatial light modulator configured for modulating the laser light emitted in the normal operating mode.

14. Apparatus, comprising:
a housing;
an illumination module configured for insertion within the housing; the illumination module including:
a battery,
a laser diode,
a Zener diode reverse coupled in parallel with the laser diode in a laser diode/reversed Zener diode coupling,
a laser driver, and
a circuit connecting the laser diode/reversed Zener diode coupling to the laser driver to apply voltage in a normal operating polarity direction at a first magnitude to cause the laser diode to emit laser light in a normal operating mode, and switchable to a laser damaging mode to connect the laser diode/reversed Zener diode coupling to the battery to apply voltage in an opposite, reversed polarity direction at a second magnitude to cause the laser diode to be rendered damaged for further emitting laser light in the normal operating mode; and
an interlock connecting the illumination module within the housing; the interlock including a mechanism configured to automatically switch the circuit from the normal operating mode configuration to the laser damaging mode configuration, upon removal of the illumination module from the housing.
